(19) United States
(12) Patent Application Publication
(10) Pub. No.: US 2026/0082988 A1
(43) Pub. Date: Mar. 19, 2026

(54) SEMICONDUCTOR DEVICE AND MANUFACTURING METHOD THEREOF

(71) Applicant: FUJI ELECTRIC CO., LTD., Kawasaki-shi (JP)

(72) Inventor: Nobuhiro HIGASHI, Matsumoto-city (JP)

(73) Assignee: FUJI ELECTRIC CO., LTD., Kawasaki-shi (JP)

(21) Appl. No.: 19/278,306

(22) Filed: Jul. 23, 2025

(30) Foreign Application Priority Data
Sep. 18, 2024 (JP) 2024-160906

(51) Int. Cl. H01L 23/053; H01L 21/48; H01L 21/56; H01L 23/00; H01L 23/08; H01L 23/29; H01L 23/367; H01L 23/495; H01L 25/065

(52) U.S. Cl. CPC H10W 76/15; H10W 70/023; H10W 74/01; H10W 74/40; H10W 76/18; H10W 99/00; H10W 40/22; H10W 70/427; H10W 72/865; H10W 72/884; H10W 90/00; H10W 90/734; H10W 90/736; H10W 90/754

(57) ABSTRACT

A semiconductor device includes: a heat dissipation base; a case including an outer peripheral wall that has an inner surface facing an inside of the case and a wiring terminal provided integrally with the outer peripheral wall, the wiring terminal having an inner end portion, which is on one end of the wiring terminal and is exposed to the inside of the case from the inner surface of the outer peripheral wall; a sealing member sealing the inside of the case; and an adhesion member embedded in the inner surface of the case and having an adhesion surface exposed from the inner surface, the adhesion member and the heat dissipation base being on different sides of the inner end portion. The adhesion surface has higher adhesion to the sealing member than the outer peripheral wall.

### CROSS-REFERENCE TO RELATED APPLICATION

This application is based upon and claims the benefit of priority of the prior Japanese Patent Application No. 2024-160906, filed on Sep. 18, 2024, the entire contents of which are incorporated herein by reference.

### BACKGROUND OF THE INVENTION

### 1. Field of the Invention

The embodiments discussed herein relate to a semiconductor device and a manufacturing method thereof.

### 2. Background of the Related Art

A semiconductor device includes semiconductor chips, substrates on which the semiconductor chips are disposed, a case storing the semiconductor chips and the substrates, and a sealing member sealing the inside of the case (see, for example, Japanese Laid-open Patent Publication No. 2021-184449, Japanese Laid-open Patent Publication No. 2005-064398, and Japanese Laid-open Patent Publication No. 2016-100475).

### SUMMARY OF THE INVENTION

According to an aspect of the present disclosure, there is provided a semiconductor device, including: a heat dissipation base having a top surface; a case, including: an outer peripheral wall, which is disposed on the top surface of the heat dissipation base, and has an inner surface facing an inside of the case, and a wiring terminal provided integrally with the outer peripheral wall, the wiring terminal having an inner end portion, which is on one end of the wiring terminal and is exposed to the inside of the case from the inner surface of the outer peripheral wall; a sealing member sealing the inside of the case; and an adhesion member, which is embedded in the inner surface of the case and has an adhesion surface exposed from the inner surface, the adhesion member and the heat dissipation base being on different sides of the inner end portion of the wiring terminal, wherein the adhesion surface has higher adhesion to the sealing member than the outer peripheral wall.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device (without sealing);

FIG. 2 is a side view of the semiconductor device;

FIG. 3 is a plan view of a semiconductor unit;

FIG. 4 is a first cross-sectional view of the semiconductor unit;

FIG. 5 is a second cross-sectional view of the semiconductor unit;

FIG. 6 is a first cross-sectional view of the semiconductor device according to the first embodiment;

FIG. 7 is a second cross-sectional view of the semiconductor device according to the first embodiment;

FIG. 8 is a third cross-sectional view of the semiconductor device according to the first embodiment;

FIG. 9 is a flowchart of a method of manufacturing the semiconductor device according to the first embodiment;

FIG. 10 is a flowchart of a case manufacturing process according to the first embodiment;

FIG. 11 is a diagram illustrating a mold used in the case manufacturing process according to the first embodiment;

FIG. 12 is a diagram illustrating a component setting step included in the case manufacturing process according to the first embodiment;

FIG. 13 is a diagram illustrating a mold clamping step included in the case manufacturing process according to the first embodiment;

FIG. 14 is a diagram illustrating a molding step included in the case manufacturing process according to the first embodiment; and

FIG. 15 is a cross-sectional view of semiconductor device according to a second embodiment.

### DETAILED DESCRIPTION OF THE INVENTION

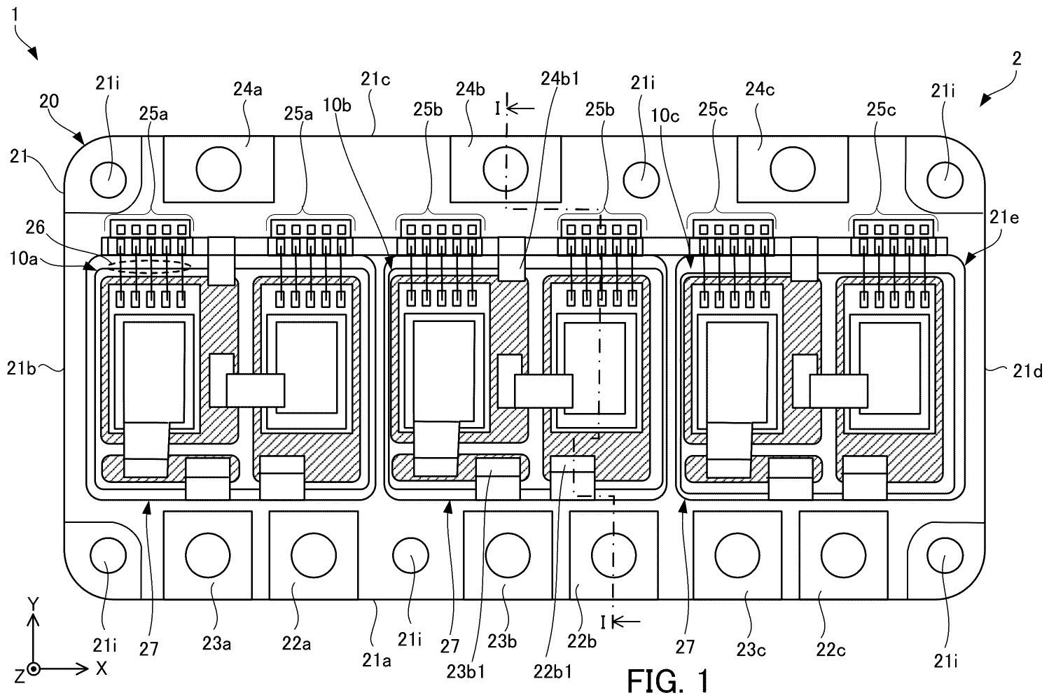

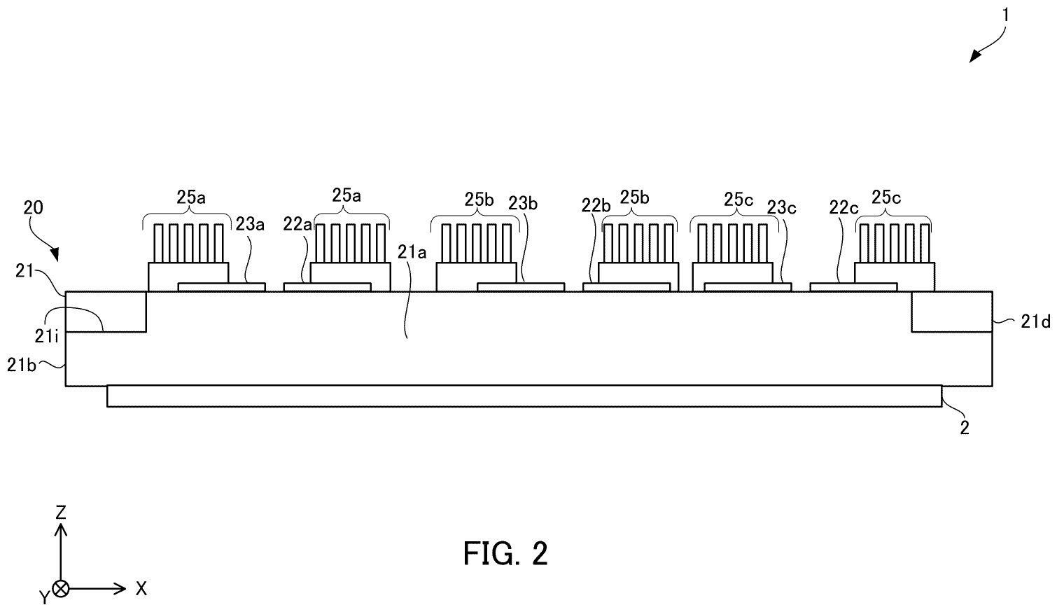

Hereinafter, embodiments will be described with reference to the accompanying drawings. In the following description, regarding a semiconductor device 1 in FIGS. 1 and 2, terms “front surface” and “top surface” each express the X-Y plane facing upward (+Z direction). Likewise, regarding the semiconductor device 1 in FIGS. 1 and 2, a term “up” expresses the upward direction (+Z direction). Regarding the semiconductor device 1 in FIGS. 1 and 2, terms “rear surface” and “bottom surface” each express the X-Y plane facing downward (−Z direction). Likewise, regarding the semiconductor device 1 in FIGS. 1 and 2, a term “down” expresses the downward direction (−Z direction). As needed, the above terms also mean their respective directions in the other drawings. Regarding the semiconductor device 1 in FIGS. 1 and 2, terms “higher level” and “upper level” express an upper location (+Z direction). Likewise, regarding the semiconductor device 1 in FIGS. 1 and 2, a term “lower level” expresses a lower location (−Z direction). The terms “front surface”, “top surface”, “up”, “rear surface”, “bottom surface”, “down”, and “side surface” are simply used as convenient expressions to determine relative positional relationships, and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, an expression “approximately the same” may be used when an error between two elements is within +10%. In addition, even when two elements are not exactly perpendicular, orthogonal, or parallel to each other, the two elements may be described as being “perpendicular”, “orthogonal”, or “parallel” to each other if the error is within +10°.

### First Embodiment

The semiconductor device 1 according to a first embodiment will be described with reference to FIGS. 1 and 2. FIG. 1 is a plan view of the semiconductor device (without sealing), and FIG. 2 is a side view of the semiconductor device. In FIG. 1, a sealing member is omitted. FIG. 2 is a side view of the X-Z plane in FIG. 1 as viewed in the +Y direction.

The semiconductor device 1 may include a heat dissipation base 2. The semiconductor device 1 includes semiconductor units 10a, 10b, and 10c, and also includes a case 20 that stores the semiconductor units 10a, 10b, and 10c. The semiconductor units 10a, 10b, and 10c stored in the case 20 are sealed by a sealing member 30 described later.

The semiconductor units 10a, 10b, and 10c have the same configuration. Each of the semiconductor units 10a, 10b, and 10c will be described as a semiconductor unit 10 when they are not distinguished from each other. Details of the semiconductor unit 10 will be described later.

First, the case 20 includes a frame portion 21 and wiring terminals (first connection terminals 22a, 22b, and 22c, second connection terminals 23a, 23b, and 23c, a U-phase output terminal 24a, a V-phase output terminal 24b, a W-phase output terminal 24c, and control terminals 25a, 25b, and 25c). The case 20 may include a storage cover that is provided at an opening portion 21e described later and that covers unit storage portions 27 as needed.

The frame portion 21 has a substantially rectangular shape in plan view, and includes outer peripheral walls 21a, 21b, 21c, and 21d sequentially provided in four directions. The outer peripheral walls 21a and 21c extend in the longitudinal direction corresponding to the long sides of the frame portion 21, and the outer peripheral walls 21b and 21d extend in the lateral direction corresponding to the short sides of the frame portion 21. In addition, corner portions which are the connection portions where two of the outer peripheral walls 21a, 21b, 21c, and 21d meet may have an angle such as a right angle, or may be rounded as illustrated in FIG. 1. Fastening holes 21i penetrating the frame portion 21 are formed at the corner portions in the front surface of the frame portion 21. The fastening holes 21i formed in such corner portions of the frame portion 21 may be formed below the front surface of the frame portion 21.

The frame portion 21 (the outer peripheral walls 21a, 21b, 21c, and 21d included in the frame portion 21) surrounds four sides of the opening portion 21e. The opening portion 21e has a rectangular shape in plan view, and are open from the top surface to the bottom surface of the frame portion 21. Further, the frame portion 21 includes a plurality of unit storage portions 27 in the opening portion 21e. Here, the number of the unit storage portions 27 is three. The unit storage portions 27 are provided in the opening portion 21e sequentially along the outer peripheral walls 21a and 21c. A step may be provided on the inner surface of the outer peripheral wall 21c of each unit storage portion 27. The inner surface and the step will be described later. The semiconductor units 10a, 10b, and 10c are stored in their respective unit storage portions 27.

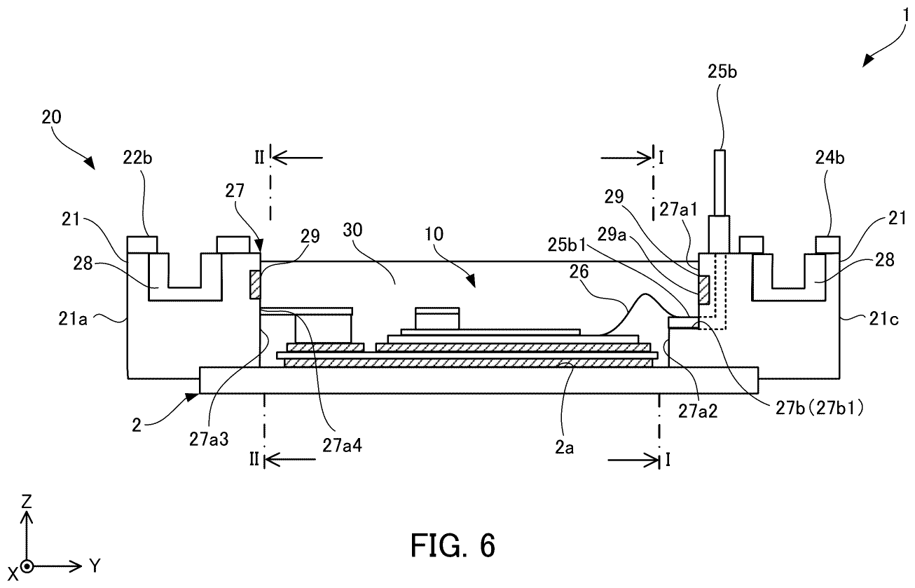

The semiconductor units 10a, 10b, and 10c are bonded to a placement surface 2a (see FIG. 6) of the heat dissipation base 2. When the frame portion 21 is attached to the placement surface 2a of the heat dissipation base 2, the semiconductor units 10a, 10b, and 10c are stored in their respective unit storage portions 27 of the frame portion 21. The frame portion 21 is bonded to the placement surface 2a of the heat dissipation base 2 with an adhesive.

The frame portion 21 includes the first connection terminals 22a, 22b, and 22c and the second connection terminals 23a, 23b, and 23c on the top surface of the outer peripheral wall 21a in plan view. The outer end portion of each of the first connection terminals 22a, 22b, and 22c and the second connection terminals 23a, 23b, and 23c may be disposed on the top surface of the outer peripheral wall 21a. An opening hole may be formed in the individual outer end portion. On the top surface of the frame portion 21 on which the individual outer end portion is disposed, a nut 28 (see FIG. 6) may be stored so as to face the opening hole of the corresponding outer end portion. The inner end portion of each of the above-described terminals is exposed in a corresponding unit storage portion 27 and is electrically connected to a corresponding one of the semiconductor units 10a, 10b, and 10c. The portion between the outer end portion and the inner end portion of each of the first connection terminals 22a, 22b, and 22c and the second connection terminals 23a, 23b, and 23c is provided in the frame portion 21 (the outer peripheral wall 21a).

The frame portion 21 includes the U-phase output terminal 24a, the V-phase output terminal 24b, and the W-phase output terminal 24c on the outer peripheral wall 21c in plan view. The outer end portion (an external connection portion) of each of the U-phase output terminal 24a, the V-phase output terminal 24b, and the W-phase output terminal 24c is disposed on the top surface of the outer peripheral wall 21c. An opening hole may be formed in the individual outer end portion. On the top surface of the frame portion 21 (the outer peripheral wall 21c) on which the individual outer end portion is disposed, a nut 28 (see FIG. 6) may be stored so as to face the opening hole of the corresponding outer end portion. The inner end portion (an inner joint portion) of each of the above-described terminals is exposed in a corresponding unit storage portion 27 and is electrically connected to a corresponding one of the semiconductor units 10a, 10b, and 10c. The portion (a wiring portion) between the outer end portion and the inner end portion of each of the U-phase output terminal 24a, the V-phase output terminal 24b, and the W-phase output terminal 24c is provided in the frame portion 21 (the outer peripheral wall 21c).

Therefore, the frame portion 21 includes the first connection terminal 22a and the second connection terminal 23a on the top surface of the outer peripheral wall 21a, and includes the U-phase output terminal 24a on the top surface of the outer peripheral wall 21c, with a unit storage portion 27 interposed therebetween in plan view. Similarly, the frame portion 21 includes the first connection terminal 22b and the second connection terminal 23b on the top surface of the outer peripheral wall 21a, and includes the V-phase output terminal 24b on the top surface of the outer peripheral wall 21c, with a unit storage portion 27 interposed therebetween in plan view. Similarly, the frame portion 21 includes the first connection terminal 22c and the second connection terminal 23c on the top surface of the outer peripheral wall 21a, and includes the W-phase output terminal 24c on the top surface of the outer peripheral wall 21c, with a unit storage portion 27 interposed therebetween in plan view.

The frame portion 21 further includes the control terminals 25a, 25b, and 25c on the top surface of the outer peripheral wall 21c near the unit storage portions 27 along the outer peripheral wall 21c in plan view. The control terminals 25a may be divided into two groups. One group may be located on the left side and the other group may be located on the right side in the corresponding unit storage portion 27. The control terminals 25b and 25c may be formed in the same way. In this case, the two groups of control terminals 25a may be provided so as to sandwich the inner end portion of the U-phase output terminal 24a. Similarly, the two groups of control terminals 25b may be provided so as to sandwich the inner end portion of the V-phase output terminal 24b. Similarly, the two groups of control terminals 25c may be provided so as to sandwich the inner end portion of the W-phase output terminal 24c. The outer end portions of the control terminals 25a, 25b, and 25c extend vertically upward (+Z direction) from the top surface of the outer peripheral wall 21c of the frame portion 21. The inner end portions of the control terminals 25a, 25b, and 25c extend toward the inside (−Y direction) from the outer peripheral wall 21c of their respective unit storage portions 27, and are disposed such that the upper portions of the inner end portions are exposed.

The wiring terminals (the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c) are made of a metal having excellent conductivity. The metal is, for example, copper, aluminum, or an alloy containing at least one of these elements as a main component. The surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c may be plated. In this case, the plating material used is, for example, nickel, a nickel-phosphorus alloy, or a nickel-boron alloy.

In addition, adhesion members 29 are formed in the inner surface of the outer peripheral wall 21a which faces the unit storage portions 27 inside the frame portion 21 and in which the first connection terminals 22a, 22b, and 22c and the second connection terminals 23a, 23b, and 23c are provided. Adhesion members 29 are formed in the inner surface of the outer peripheral wall 21c which faces the unit storage portions 27 inside the frame portion 21 and in which the U-phase output terminal 24a, the V-phase output terminal 24b, and the W-phase output terminal 24c are provided. Details of these adhesion members 29 will be described later.

The frame portion 21 includes the wiring terminals (the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c), and may be integrally molded by injection molding using a thermoplastic resin. In this case, the adhesion members 29 may also be integrally molded. Examples of the thermoplastic resin include a polyphenylene sulfide (PPS) resin, a polybutylene terephthalate (PBT) resin, a polybutylene succinate (PBS) resin, a polyamide (PA) resin, and an acrylonitrile butadiene styrene (ABS) resin. Herein, for example, the frame portion 21 may be made of a polyphenylene sulfide (PPS) resin. Details of a method of manufacturing the case 20 will be described later.

The sealing member 30 (see FIG. 6) that seals the unit storage portions 27 inside the frame portion 21 may be a thermosetting resin. Examples of the thermosetting resin include an epoxy resin, a phenol resin, a maleimide resin, and a polyester resin. Alternatively, the sealing member 30 may be silicone gel. Herein, the sealing member 30 is an epoxy resin.

The sealing member 30 seals all the semiconductor units 10a, 10b, and 10c stored in their respective unit storage portions 27, and does not need to seal the entire unit storage portions 27. It is desirable that all wires 26 and portions of the wiring terminals (the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c), the portions being exposed in the unit storage portions 27, be sealed.

The storage cover (not illustrated) has a shape that faces the opening portion 21e of the frame portion 21 in plan view, and is attached to the opening portion 21e of the frame portion 21. The storage cover may also be formed by injection molding using the same material as the frame portion 21.

The heat dissipation base 2 has, on its top surface, the placement surface 2a (see FIG. 6) on which the semiconductor units 10a, 10b, and 10c are placed. Specifically, as described above, the frame portion 21 is attached to the placement surface 2a of the heat dissipation base 2 on which the semiconductor units 10a, 10b, and 10c are arranged. The heat dissipation base 2 is disposed on the rear surface of the case 20 and is flat. The heat dissipation base 2 may include, for example, heat dissipation fins. Alternatively, instead of the heat dissipation base 2, a cooling device which includes a cooling surface to which the case 20 is connected and on which the semiconductor units 10a, 10b, and 10c are disposed may be used. In this case, a coolant circulates inside the cooling device.

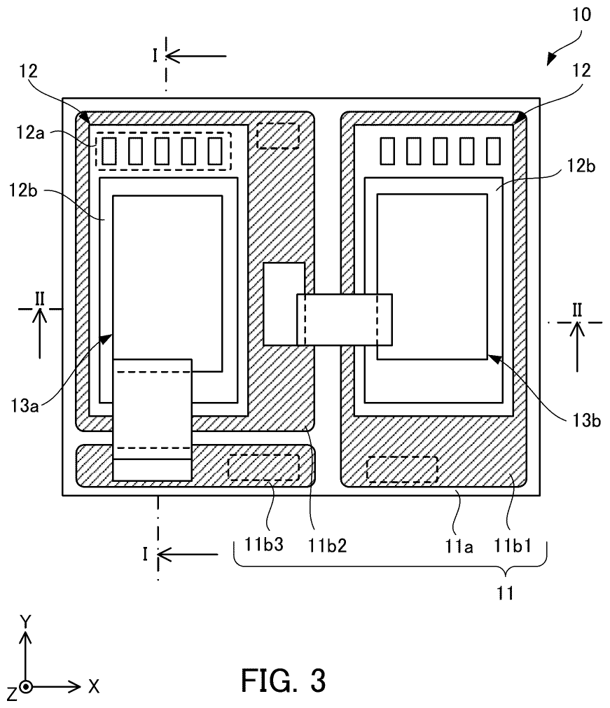

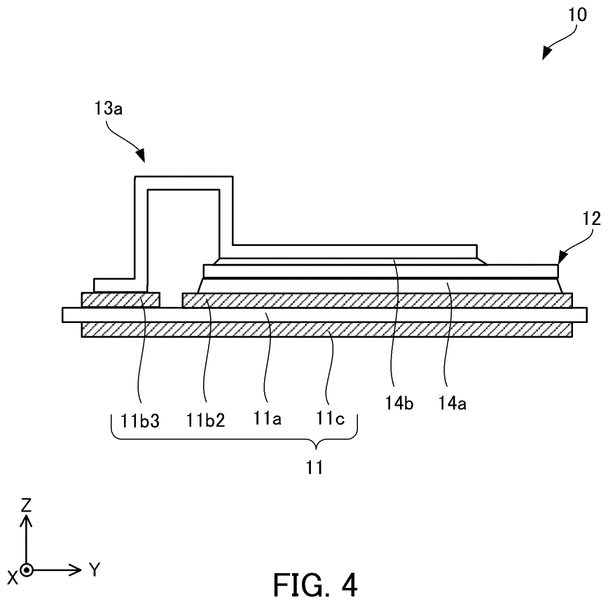

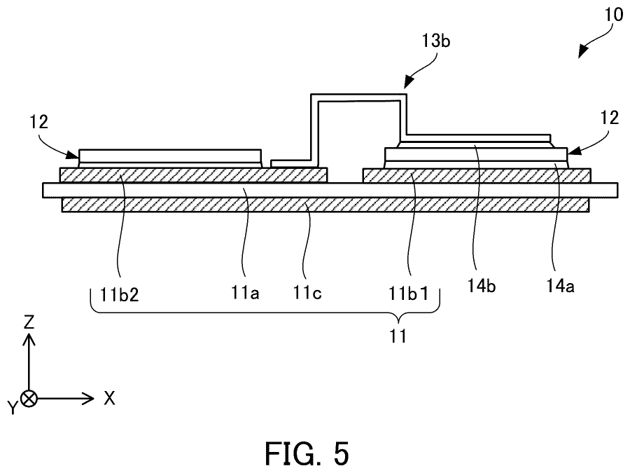

Next, the semiconductor units 10a, 10b, and 10c (the semiconductor units 10) will be described with reference to FIGS. 3 to 5. FIG. 3 is a plan view of a semiconductor unit. FIG. 4 is a first cross-sectional view of the semiconductor unit, and FIG. 5 is a second cross-sectional view of the semiconductor unit. FIG. 4 is a cross-sectional view taken along an alternate long and short dash line I-I in FIG. 3, and FIG. 5 is a cross-sectional view taken along an alternate long and short dash line II-II in FIG. 3.

The semiconductor unit 10 may be a device constituting an inverter circuit for one phase. The semiconductor unit 10 includes an insulated circuit substrate 11, two semiconductor chips 12, and lead frames 13a and 13b. The individual semiconductor chip 12 is bonded to the insulated circuit substrate 11 by a bonding member 14a. Each of the lead frames 13a and 13b is bonded to the main electrode on the top surface of the corresponding semiconductor chip 12 and to the top surface of the insulated circuit substrate 11 by a bonding member 14b. The lead frames 13a and 13b may be bonded to the insulated circuit substrate 11 by ultrasonic bonding, instead of the bonding members 14b.

The insulated circuit substrate 11 includes an insulating plate 11a, wiring boards 11b1, 11b2, and 11b3, and a metal plate 11c. The insulating plate 11a has a rectangular shape in plan view. Corner portions of the insulating plate 11a may be rounded or chamfered.

The insulating plate 11a is made of a material having an insulating property and excellent thermal conductivity. The insulating plate 11a is made of ceramics. Examples of the ceramics include aluminum oxide, aluminum nitride, and silicon nitride.

The wiring boards 11b1, 11b2, and 11b3 are examples of conductive plates, and are formed on the front surface of the insulating plate 11a. The wiring boards 11b1, 11b2, and 11b3 are made of a metal having excellent conductivity. The metal is, for example, copper, aluminum, or an alloy containing at least one of these elements as a main component. The surfaces of the wiring boards 11b1, 11b2, and 11b3 may be plated to improve corrosion resistance. In this case, the plating material used is, for example, nickel, a nickel-phosphorus alloy, or a nickel-boron alloy.

The wiring board 11b1 is a half region on the +X direction side of the front surface of the insulating plate 11a, and occupies the entire region from the −Y direction side to the +Y direction side. An end (the inner end) of a corresponding one of the first connection terminals 22a, 22b, and 22c is bonded to a region surrounded by a broken line illustrated in the wiring board 11b1. The region surrounded by the broken line illustrated in the wiring board 11b1 and the end portion of the corresponding one of the first connection terminals 22a, 22b, and 22c may be bonded to each other via a conductive block body.

The wiring board 11b2 occupies a half region on the −X direction side of the front surface of the insulating plate 11a. Further, the wiring board 11b2 extends from the +Y direction side to a portion a little before the −Y direction side on the front side of the insulating plate 11a. An end (the inner end) of a corresponding one of the U-phase output terminal 24a, the V-phase output terminal 24b, and the W-phase output terminal 24c is bonded to a region surrounded by a broken line illustrated in the wiring board 11b2. The region surrounded by the broken line illustrated in the wiring board 11b2 may be bonded to a corresponding one of the U-phase output terminal 24a, the V-phase output terminal 24b, and the W-phase output terminal 24c via a conductive block body.

The wiring board 11b3 occupies a region surrounded by the wiring boards 11b1 and 11b2 on the top surface of the insulating plate 11a. An end of a corresponding one of the second connection terminals 23a, 23b, and 23c is bonded to a region surrounded by a broken line illustrated in the wiring board 11b3. The region surrounded by the broken line illustrated in the wiring board 11b3 and the end of the corresponding one of the second connection terminals 23a, 23b, and 23c may be connected to each other via a conductive block body.

The metal plate 11c is formed on the bottom surface of the insulating plate 11a. The metal plate 11c has a rectangular shape. The area of the metal plate 11c in plan view is smaller than the area of the insulating plate 11a and larger than the area of the region where the wiring boards 11b1, 11b2, and 11b3 are formed. Corner portions of the metal plate 11c may be rounded or chamfered. The metal plate 11c is formed on the entire surface of the insulating plate 11a except for the edge portion thereof. The metal is, for example, copper, aluminum, or an alloy containing at least one of these elements. The surface of the metal plate 11c may be plated in order to improve corrosion resistance. In this case, the plating material used is, for example, nickel, a nickel-phosphorus alloy, or a nickel-boron alloy.

For example, a direct copper bonding (DCB) substrate or an active metal brazed (AMB) substrate may be used as the insulated circuit substrate 11 having the above-described structure. The insulated circuit substrate 11 may be attached to the front surface, that is, the placement surface 2a, of the heat dissipation base 2 via a bonding member (not illustrated). The heat generated by the semiconductor chips 12 is conducted to the heat dissipation base 2 via the wiring boards 11b1 and 11b2, the insulating plate 11a, and the metal plate 11c, and is consequently dissipated.

The bonding members 14a and 14b are solder. As the solder, lead-free solder is used. The lead-free solder contains, for example, an alloy containing at least two of tin, silver, copper, zinc, antimony, indium, and bismuth as a main component. Further, the solder may contain an additive. The additive is, for example, nickel, germanium, cobalt, or silicon. When the solder contains an additive, wettability, gloss, and bonding strength are improved, and reliability is consequently improved. In particular, a sintered body may be used as the bonding member 14a instead of solder. If the bonding is performed by using a sintered body, the sintered material is, for example, powder of silver, iron, copper, aluminum, titanium, nickel, tungsten, or molybdenum.

A bonding member (not illustrated) for bonding the individual semiconductor unit 10 and the heat dissipation base 2 is solder. As the solder, lead-free solder is used. The lead-free solder contains, for example, an alloy containing at least two of tin, silver, copper, zinc, antimony, indium, and bismuth as a main component. Further, the solder may contain an additive. The additive is, for example, nickel, germanium, cobalt, or silicon. The bonding member may be a brazing material or a thermal interface material. The brazing material contains, for example, at least one of an aluminum alloy, a titanium alloy, a magnesium alloy, a zirconium alloy, and a silicon alloy as a main component. Examples of the thermal interface material include various materials such as thermally conductive grease, elastomer sheet, room temperature vulcanization (RTV) rubber, gel, and phase change material. By attaching the semiconductor units 10 to the heat dissipation base 2 via such a brazing material or thermal interface material, the heat dissipation performance of the semiconductor units 10 is improved.

The individual semiconductor chip 12 includes a power device element made mainly of silicon. The power device element is a reverse conducting-insulated gate bipolar transistor (RC-IGBT). The RC-IGBT has both functions of an IGBT, which is a switching element, and a freewheeling diode (FWD), which is a diode element. Control electrodes 12a (gate electrodes or the like) and an output electrode (an emitter electrode), which is a main electrode 12b, are provided on the top surface of the semiconductor chip 12. An input electrode (a collector electrode), which is a main electrode, is provided on the bottom surface of the semiconductor chip 12. The control electrodes 12a are provided along one side of the top surface of the semiconductor chip 12 (or in the center of one side). The output electrode is provided in the center of the top surface of the semiconductor chip 12.

The semiconductor chip 12 may include a switching element formed of a power MOSFET mainly made of silicon carbide. The semiconductor chip 12 includes control electrodes 12a (gate electrodes or the like) and an output electrode (a source electrode), which is a main electrode 12b, on the front surface. The semiconductor chip 12 includes an input electrode (a drain electrode), which is a main electrode, on the rear surface.

Further, the individual semiconductor chip 12 may use a set of a switching element and a diode element which are mainly made of silicon or silicon carbide. The switching element is, for example, an IGBT or a power MOSFET. The individual semiconductor chip 12 includes, for example, an input electrode (a drain electrode or a collector electrode) as a main electrode on the rear surface, and control electrodes 12a (gate electrodes) and an output electrode (a source electrode or an emitter electrode), which is a main electrode 12b, on the front surface. The diode element is, for example, an FWD such as a Schottky barrier diode (SBD) or a P-Intrinsic-N (PIN) diode. The individual semiconductor chip 12 includes an output electrode (a cathode electrode) as a main electrode on the rear surface and an input electrode (an anode electrode) as a main electrode on the front surface.

The lead frame 13a electrically connects and wires the semiconductor chip 12 and the wiring board 11b3, and the lead frame 13b electrically connects and wires the semiconductor chip 12 and the wiring board 11b2. The lead frame 13a directly connects the main electrode 12b of the semiconductor chip 12 (on the wiring board 11b2) and the wiring board 11b3 via the bonding member described above. The lead frame 13b directly connects the main electrode 12b of the semiconductor chip 12 (on the wiring board 11b1) and the wiring board 11b2 via the bonding member described above. The lead frames 13a and 13b may be bonded to the wiring boards 11b3 and 11b2 by ultrasonic bonding.

The lead frames 13a and 13b are made of a metal having excellent conductivity. The metal is, for example, copper, aluminum, or an alloy containing at least one of these elements as a main component. The surfaces of the lead frames 13a and 13b may be plated to improve corrosion resistance. In this case, the plating material used is, for example, nickel, a nickel-phosphorus alloy, or a nickel-boron alloy.

The control electrodes 12a of the semiconductor chips 12 of the semiconductor units 10a, 10b, and 10c stored in the unit storage portions 27 of the frame portion 21 are mechanically and electrically connected to the inner end portions of the control terminals 25a, 25b, and 25c by the wires 26 (see FIG. 6). The individual wire 26 contains a material having excellent conductivity as a main component. The material includes, for example, gold, copper, aluminum, or an alloy containing at least one of these elements. Preferably, the individual wire 26 may be an aluminum alloy containing a trace amount of silicon.

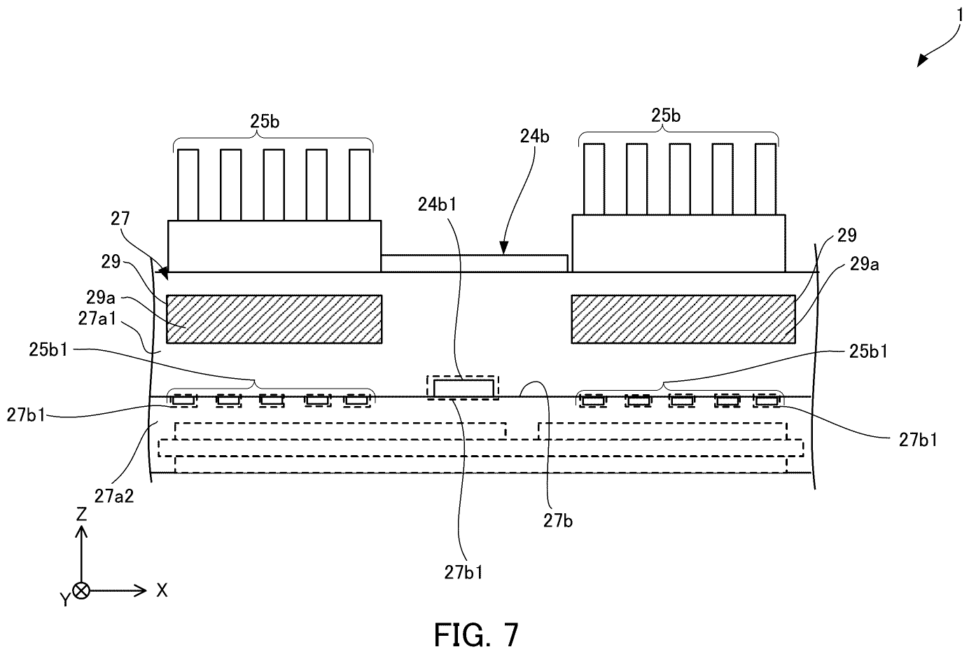

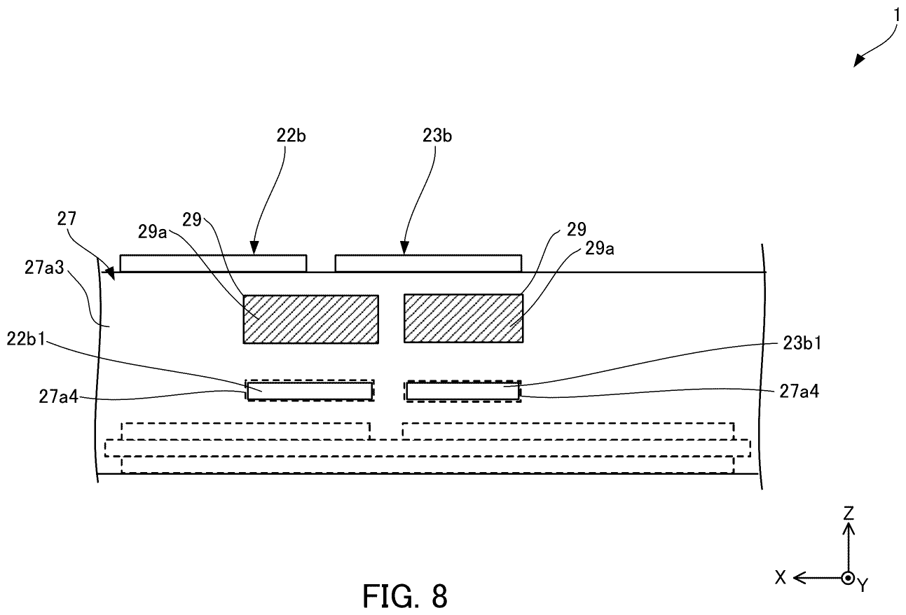

Next, the adhesion members 29 provided in the inner surfaces of the outer peripheral walls 21a and 21c at the unit storage portions 27 will be described with reference to FIGS. 6 to 8. FIG. 6 is a first cross-sectional view of the semiconductor device according to the first embodiment, FIG. 7 is a second cross-sectional view of the semiconductor device according to the first embodiment, and FIG. 8 is a third cross-sectional view of the semiconductor device according to the first embodiment. FIG. 6 is a cross-sectional view taken along an alternate long and short dash line I-I in FIG. 1. FIG. 7 is a cross-sectional view taken along an alternate long and short dash line I-I in FIG. 6, and FIG. 8 is a cross-sectional view taken along the alternate long and short dash line II-II in FIG. 6. In FIGS. 7 and 8, the insulated circuit substrate 11 is indicated by a broken line. In addition, here, the center unit storage portion 27 included in the frame portion 21 in FIG. 1 will be described as an example. The left and right unit storage portions 27 included in the frame portion 21 in FIG. 1 also include their respective adhesion members 29.

The +Y direction side and the −Y direction side of the unit storage portion 27 of the frame portion 21 are defined by the outer peripheral wall 21c and the outer peripheral wall 21a, respectively. Further, the outer peripheral wall 21c at the unit storage portion 27 includes an upper inner surface 27a1, a lower inner surface 27a2, and a step 27b on its inner side.

The upper inner surface 27a1 is parallel to the X-Z plane. The step 27b is parallel to the X-Y plane and perpendicular to the upper inner surface 27a1. An inner end portion 25b1 of the individual control terminal 25b integrally molded with the frame portion 21 is exposed on the step 27b. The step 27b may include an exposed region 27b1 where the inner end portion 25b1 of the individual control terminal 25b is exposed.

An internal connection portion 24b1 of the V-phase output terminal 24b integrally molded with the frame portion 21 is disposed on the step 27b. The step 27b may include an exposed region 27b1 that is a region where the internal connection portion 24b1 of the V-phase output terminal 24b is exposed. The lower inner surface 27a2 is parallel to the X-Z plane, is parallel to the upper inner surface 27a1, and is provided perpendicular to an end portion of the step 27b. The unit corresponding semiconductor 10 on the heat dissipation base 2 is located in a region defined by the lower inner surface 27a2 at the unit storage portion 27.

The adhesion members 29 are embedded in the upper inner surface 27a1. The individual adhesion member 29 has an adhesion surface 29a facing the corresponding unit storage portion 27. The individual adhesion member 29 is embedded in the upper inner surface 27a1 such that the adhesion surface 29a faces the unit storage portion 27. The adhesion surface 29a of the individual adhesion member 29 is flush with the upper inner surface 27a1. Further, the adhesion members 29 are provided immediately above (in the +Z direction) the inner end portions 25b1 of the control terminals 25b on the upper inner surface 27a1 when viewed in the +Y direction.

The individual adhesion member 29 is embedded in the upper inner surface 27a1 along a group of control terminals 25b arranged in the +X direction from the leftmost control terminal 25b to the rightmost control terminal 25b. Here, a case where an adhesion member 29 is provided for each of the two groups of control terminals 25b is illustrated. Alternatively, a single adhesion member 29 may be embedded in the upper inner surface 27a1 continuously along the two groups of control terminals 25b from the leftmost control terminal 25b of one group of control terminals 25b located in the −X direction to the rightmost control terminal 25b of the other group of control terminals 25b located in the +X direction.

The adhesion surface 29a of the individual adhesion member 29 is made of a material having higher adhesion to the sealing member 30 than the frame portion 21. The entire adhesion member 29 may be made of such a material. The material may be the same as the main material of the sealing member 30. Alternatively, the material may be, for example, a metal, a glass epoxy plate, a paper epoxy substrate, a paper phenol substrate, or an epoxy resin plate material. The metal may be, for example, copper, aluminum, or an alloy containing at least one of these elements.

On the other hand, the outer peripheral wall 21a at the unit storage portion 27 includes an inner surface 27a3 on the inner side. The inner surface 27a3 is parallel to the X-Z plane and faces the upper inner surface 27a1 and the lower inner surface 27a2. The first internal connection portion 22b1 of the first connection terminal 22b and the second internal connection portion 23b1 of the second connection terminal 23b protrude from the inner surface 27a3 toward the unit storage portion 27. The region of the inner surface 27a3 from which these portions protrude is an example of an exposed region 27a4.

Adhesion members 29 are also embedded in the inner surface 27a3. Adhesion surfaces 29a facing the unit storage portion 27 are also embedded in the inner surface 27a3. The adhesion surfaces 29a of the adhesion members 29 are flush with the inner surface 27a3. The adhesion members 29 are embedded in the inner surface 27a3 immediately above the first and second internal connection portions 22b1 and 23b1 of the first and second connection terminals 22b and 23b when viewed in the −Y direction. One adhesion member 29 is embedded in the inner surface 27a3 along the first internal connection portion 22b1 of the first connection terminal 22b from the left part (in the +X direction) to the right part (in the −X direction), and the other adhesion member 29 is embedded in the inner surface 27a3 along the second internal connection portion 23b1 of the second connection terminal 23b from the left part (in the +X direction) to the right part (in the −X direction). Herein, a case where an adhesion member 29 is provided for each of the first and second internal connection portions 22b1 and 23b1 of the first and second connection terminals 22b and 23b is illustrated. Alternatively, a single adhesion member 29 may be continuously embedded in the inner surface 27a3 along the first and second internal connection portions 22b1 and 23b1 from the +X direction end portion of the first internal connection portion 22b1 of the first connection terminal 22b to the −X direction end portion of the second internal connection portion 23b1 of the second connection terminal 23b.

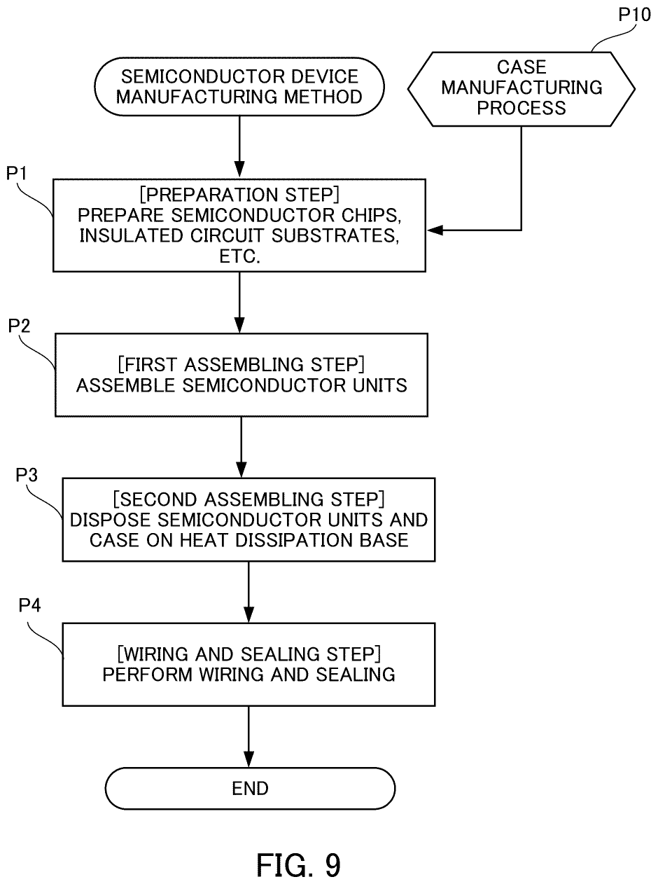

Next, a method of manufacturing the semiconductor device 1 will be described with reference to FIG. 9. FIG. 9 is a flowchart of the method of manufacturing the semiconductor device according to the first embodiment. First, a preparation step of preparing components of the semiconductor device 1 is performed (step P1). As the components, for example, the semiconductor chips 12, the insulated circuit substrates 11, the lead frames 13a and 13b, the case 20, the heat dissipation base 2, and the sealing material are prepared. In addition to these components, components needed for manufacturing the semiconductor device 1 are prepared. Further, manufacturing apparatuses and manufacturing jigs needed for manufacturing the semiconductor device 1 may be prepared.

The case 20 prepared in the preparation step may be manufactured by a case manufacturing process (process P10) before step P3 of a second assembly step after the preparation step is started. Details of process P10 will be described later.

Next, a first assembling step of assembling the semiconductor units 10 is performed (step P2). First, a solder material is disposed on the wiring boards 11b1 and 11b2 of the insulated circuit substrates 11, and the semiconductor chips 12 are disposed via the solder material. Further, the lead frames 13b and 13a are disposed on the main electrodes 12b of the semiconductor chips 12 and on the wiring boards 11b2 and 11b3 of the insulated circuit substrates 11 via a solder material. The solder material is, for example, a plate-shaped solder material. The solder material may be applied onto the wiring boards 11b1 and 11b2 as a paste-like solder material. Thereafter, the semiconductor units 10 set as described are heated such that the relevant members are bonded to each other. In this way, the semiconductor units 10 are assembled.

Next, the second assembling step of attaching the semiconductor units 10 and the case 20 to the heat dissipation base 2 is performed (step P3). First, the semiconductor units 10 are disposed on the placement surface 2a (the top surface) of the heat dissipation base 2 via a bonding member such as a solder material, a brazing material, or a thermal interface material.

Thereafter, the bottom surface of the case 20 is disposed on the placement surface 2a of the heat dissipation base 2 to which the semiconductor units 10 have been bonded via an adhesive, and the semiconductor units 10 are stored in their respective unit storage portions 27 of the case 20.

Next, a wiring and sealing step of wiring the semiconductor units 10 and sealing the inside of the unit storage portions 27 with a sealing member is performed (step P4). Each of the inner end portions of the first connection terminals 22a, 22b, and 22c, the inner end portions being exposed in the unit storage portions 27 from the case 20, is bonded to a corresponding one of the wiring boards 11b1 of the insulated circuit substrates 11 of the semiconductor units 10 by, for example, ultrasonic bonding. Similarly, each of the inner end portions of the second connection terminals 23a, 23b, and 23c is bonded to a corresponding one of the wiring boards 11b3 of the insulated circuit substrates 11 of the semiconductor units 10. Further, similarly, each of the inner end portions of the U-phase output terminal 24a, the V-phase output terminal 24b, and the W-phase output terminal 24c is bonded to a corresponding one of the wiring boards 11b2 of the insulated circuit substrates 11 of the semiconductor units 10. The inner ends of the control terminals 25a, 25b, and 25c of the case 20 are electrically connected to the control electrodes 12a of the semiconductor chips 12 by the wires 26. Next, the sealing member 30 is injected into the unit storage portions 27 to seal the semiconductor units 10. As a result, the semiconductor device 1 illustrated in FIGS. 1 and 2 is obtained.

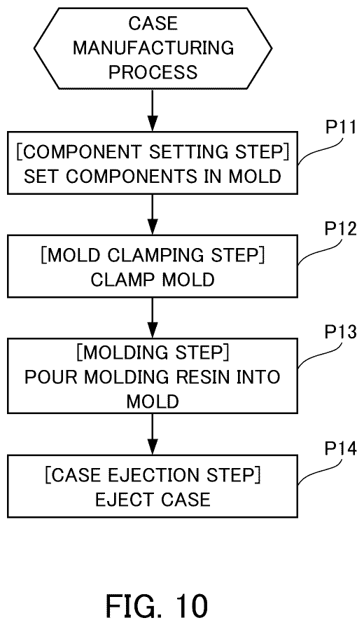

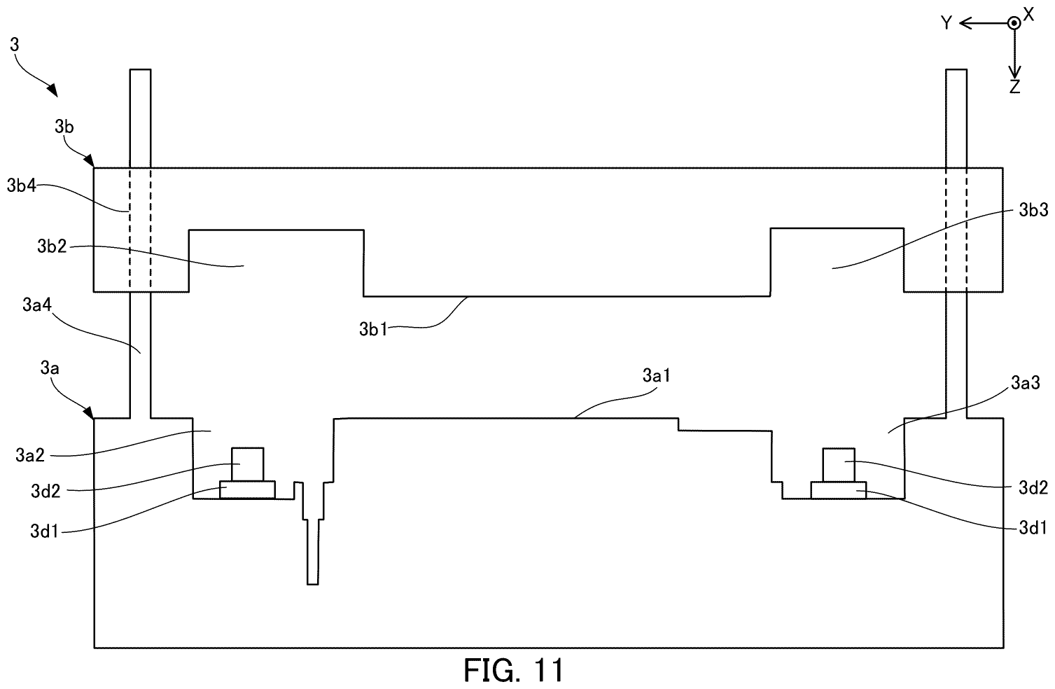

Next, the case manufacturing process (process P10) will be described with reference to FIGS. 10 to 14. FIG. 10 is a flowchart of the case manufacturing process according to the first embodiment. FIG. 11 is a diagram illustrating a mold used in the case manufacturing process according to the first embodiment.

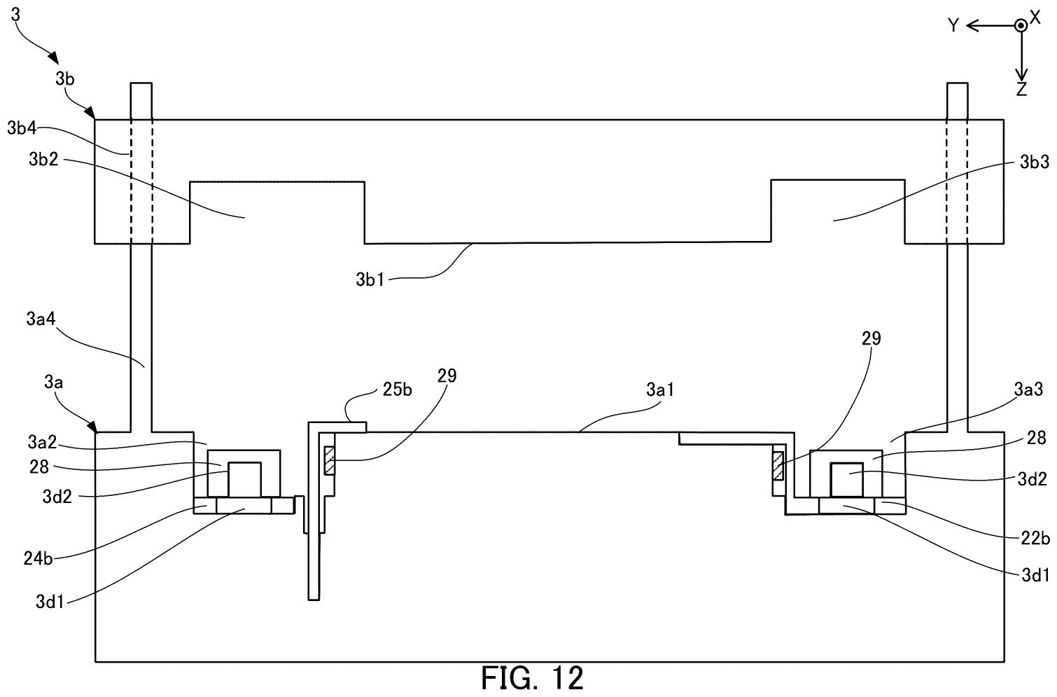

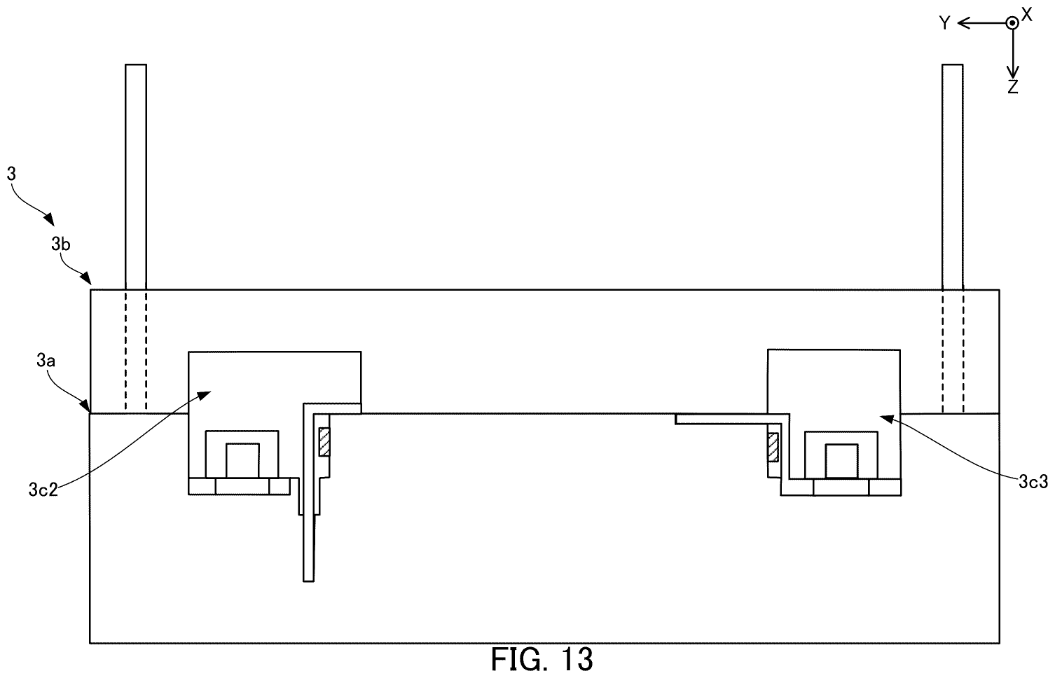

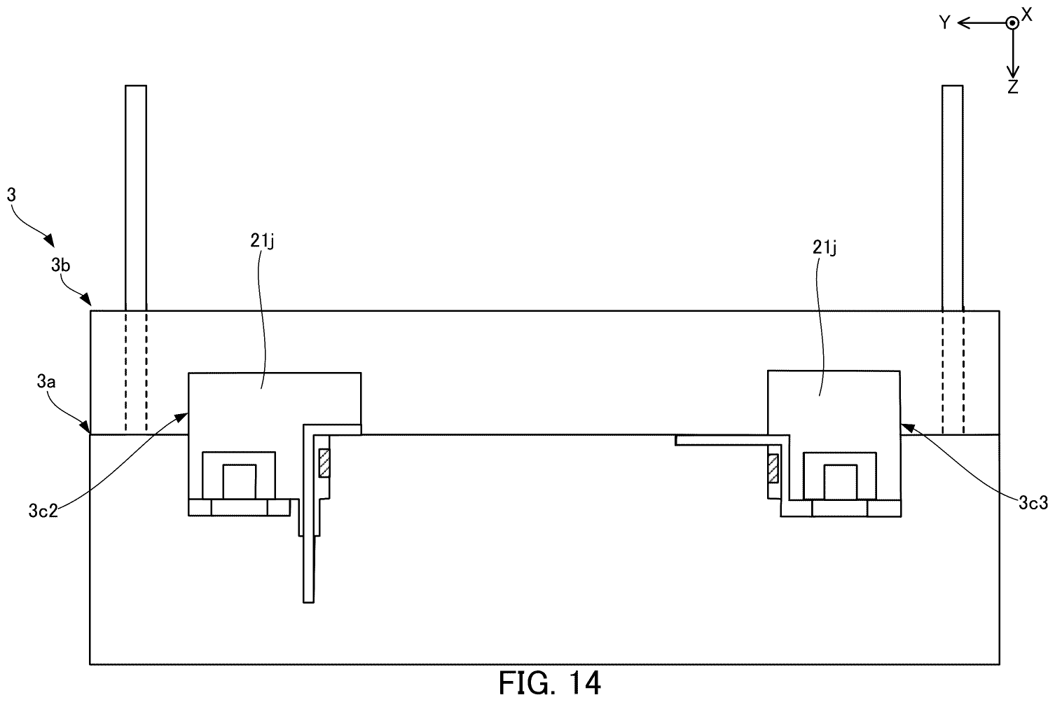

FIG. 12 is a diagram illustrating a component setting step included in the case manufacturing process according to the first embodiment. FIG. 13 is a diagram illustrating a mold clamping step included in the case manufacturing process according to the first embodiment. FIG. 14 is a diagram illustrating a molding step included in the case manufacturing process according to the first embodiment. A mold 3 illustrated in FIG. 11 molds the case 20 illustrated in FIG. 6 in a state in which the case 20 is turned upside down. The cross section of the mold 3 illustrated in FIG. 11 corresponds to the cross section of the case 20 illustrated in FIG. 6.

In order to perform the manufacturing process of the case 20, for example, the mold 3 illustrated in FIG. 11 is used. The mold 3 includes a fixed mold 3a and a movable mold 3b. The mold 3 may be made of a metal having excellent heat resistance and wear resistance. Examples of the metal include stainless steel.

The fixed mold 3a molds the top surface side of the frame portion 21 and is disposed at a predetermined position. The fixed mold 3a includes a contact surface 3a1, recesses 3a2 and 3a3, each of which is formed in a part of the contact surface 3a1, and guides 3a4. The contact surface 3a1 faces the movable mold 3b and is opposite to the movable mold 3b. The recesses 3a2 and 3a3 are formed in the contact surface 3a1. The guides 3a4 have a rod shape, are provided at, for example, four corners in plan view of the fixed mold 3a, and extend vertically upward. Further, a terminal positioning pin 3d1 and a nut positioning pin 3d2 are provided in each of the recesses 3a2 and 3a3 of the fixed mold 3a.

The terminal positioning pins 3d1 may be integrally formed with the recesses 3a2 and 3a3 of the fixed mold 3a. As described later, each of the terminal positioning pins 3d1 is attached to a corresponding one of the opening holes of the U-phase output terminal 24a, the V-phase output terminal 24b, and the W-phase output terminal 24c set in the recess 3a2. Each of the terminal positioning pins 3d1 is attached to a corresponding one of the opening holes of the first connection terminals 22a, 22b, and 22c and the second connection terminals 23a, 23b, and 23c set in the recesses 3a3. Therefore, the shape of each of the terminal positioning pins 3d1 may correspond to a corresponding one of these opening holes.

The nut positioning pins 3d2 are formed on their respective terminal positioning pins 3d1. In this case, the nut positioning pins 3d2 may be formed integrally with their respective terminal positioning pins 3d1. As described later, each of the nut positioning pins 3d2 is attached to the opening hole of a corresponding one of the nuts 28 set on the wiring terminals whose opening hole is attached to a corresponding one of the terminal positioning pins 3d1. Therefore, the shape of each of the nut positioning pins 3d2 may correspond to the opening hole of a corresponding one of the nuts 28.

The movable mold 3b molds the bottom surface side of the frame portion 21. The movable mold 3b also includes a contact surface 3b1, recesses 3b2 and 3b3, each of which is formed in a part of the contact surface 3b1, and guide holes 3b4. The contact surface 3b1 faces the fixed mold 3a and is opposite to the fixed mold 3a. As will be described later, when the movable mold 3b is set with respect to the fixed mold 3a, the contact surface 3b1 of the movable mold 3b comes into contact with the contact surface 3a1 of the fixed mold 3a, and a parting line is formed by the contact surface 3a1 and the contact surface 3b1. The recesses 3b2 and 3b3 are formed in the contact surface 3b1. The guide holes 3b4 are formed at locations such that the guide holes 3b4 correspond to the guides 3a4 when the movable mold 3b is disposed to face the fixed mold 3a. Each guide 3a4 is inserted into a corresponding one of the guide holes 3b4, and the movable mold 3b is movable up and down along the guides 3a4.

First, the component setting step of setting the components to be integrally molded with the case 20 in the mold 3 is performed (step P11). The terminal positioning pins 3d1 and the nut positioning pins 3d2 are set in advance in the recesses 3a2 and 3a3 of the fixed mold 3a. The U-phase output terminal 24a, the V-phase output terminal 24b, the W-phase output terminal 24c, and the control terminals 25a, 25b, and 25c are set in the recess 3a2 of the fixed mold 3a, and the opening holes of these wiring terminals are attached to their respective terminal positioning pins 3d1. Further, the first connection terminals 22a, 22b, and 22c and the second connection terminals 23a, 23b, and 23c are set in the recess 3a3, and the opening holes of these wiring terminals are attached to their respective terminal positioning pins 3d1. FIG. 12 illustrates a case where the V-phase output terminal 24b, the control terminals 25b, and the first connection terminal 22b are set in the recesses 3a2 and 3a3. Further, the nuts 28 are set on the nut positioning pins 3d2 in the recesses 3a2 and 3a3 of the fixed mold 3a. FIG. 12 illustrates a case where the nuts 28 are set on the nut positioning pins 3d2 on the V-phase output terminal 24b and the first connection terminal 22b in the recesses 3a2 and 3a3.

Further, the adhesion members 29 are set on the inner surfaces of the recesses 3a2 and 3a3. Note that, in FIG. 12, the adhesion members 29 are illustrated so that where the adhesion members 29 are set is easily seen. The specific setting state of the adhesion members 29 with respect to the fixed mold 3a is simply illustrated.

Next, the mold clamping step of clamping the mold 3 is performed (step P12). As illustrated in FIG. 13, the movable mold 3b is moved toward the fixed mold 3a, and the contact surface 3b1 of the movable mold 3b comes into contact with the contact surface 3a1 of the fixed mold 3a. The fixed mold 3a and the movable mold 3b are clamped. Thus, a cavity 3c2 is formed as the recesses 3a2 and 3b2 is combined, and a cavity 3c3 is formed as the recesses 3a3 and 3b3 is combined.

Next, a molding step of pouring a molding resin into the mold 3 is performed (step P13). The mold 3 clamped in step P12 is maintained at a certain temperature, and polyphenylene sulfide resin as a molding resin 21j is poured into the cavities 3c2 and 3c3 of the mold 3. Accordingly, as illustrated in FIG. 14, in the cavities 3c2 and 3c3, the outside of the nuts 28 and regions of the wiring terminals, the regions being exposed to the cavities 3c2 and 3c3, are sealed with the molding resin 21j. In addition, portions of the adhesion members 29, the portions being exposed to the cavities 3c2 and 3c3 are also sealed with the molding resin. The frame portion 21 (the outer peripheral walls 21a, 21b, 21c, and 21d) including the wiring terminals and the adhesion members 29 is molded in the mold 3.

Next, a case ejection step of ejecting the case 20 from the mold 3 is performed (step P14). When the pouring of the molding resin 21j is completed in step P13 and the mold 3 is cooled, the mold 3 is opened, the movable mold 3b is removed from the fixed mold 3a, and the terminal positioning pins 3d1 and the nut positioning pins 3d2 are removed. As a result, the nuts 28 are stored in the frame portion 21, and the case 20 in which the wiring terminals and the adhesion members 29 are integrally molded is taken out. The case 20 is molded as described above. The case 20 manufactured in this manner is used in step P3 and subsequent steps in the flowchart in FIG. 9.

Hereinafter, as a reference example of the semiconductor device 1, a semiconductor device not including the adhesion members 29 will be described. The semiconductor device according to the reference example has the same configuration as the semiconductor device 1 except for the adhesion members 29. FIG. 6 (excluding the adhesion members 29) may be referred to for the semiconductor device according to the reference example.

The semiconductor device according to the reference example is also manufactured by filing the unit storage portions 27 with the sealing member 30. The frame portion 21 of the case 20 is made of polyphenylene sulfide resin, and the sealing member 30 is made of epoxy resin. The adhesion strength between these resins is low. Specifically, the adhesion strength between the polyphenylene sulfide resin (the frame portion 21) and the epoxy resin (the sealing member 30) is about 5 MPa.

Therefore, the sealing member 30 is easily peeled off from the frame portion 21. Specifically, the sealing member 30 and the frame portion 21 have different linear expansion coefficients. Thus, when the temperature repeatedly increases and decreases during operation of the semiconductor device 1, thermal stress is generated. As a result, peeling occurs in the vicinity of the upper portion of the bonding portion between the sealing member 30 and the frame portion 21. The peeling progresses in the −Z direction of the frame portion 21. Specifically, when the peeling progresses to, for example, the bonding portion of a wire 26, breakage of the bonding portion of the wire 26 could be caused. In addition, when the peeling progresses, there is a concern that the sealing member 30 may be cracked in the inner direction, and such cracking of the sealing member may cause, for example, breakage of the bonding portion of a wire 26. Such breakage is less likely to occur in the wiring terminals of the semiconductor device than in the wires 26.

Therefore, the semiconductor device 1 includes the heat dissipation base 2 including the placement surface 2a, the case 20 including the frame-shaped frame portion 21 (the outer peripheral walls 21a, 21b, 21c, and 21d) disposed on the placement surface 2a of the heat dissipation base 2 and the control terminals 25b formed integrally with the frame portion 21 and including the inner end portions 25b1 on one end of the control terminals 25b, the inner end portions 25b1 being exposed to the inside of the case 20 from the inner surface of the frame portion 21, and the sealing member 30 sealing the inside of the case 20 on the placement surface 2a of the heat dissipation base 2. The adhesion members 29 including the adhesion surfaces 29a exposed on the upper inner surface 27a1 of the frame portion 21 are embedded in the inner surface of the frame portion 21 of the case 20 on a side of the inner end portions 25b1 in the case 20, the side being opposite to the heat dissipation base 2, and the adhesion surfaces 29a have higher adhesion to the sealing member 30 than the frame portion 21. For example, the frame portion 21 is made of polyphenylene sulfide resin, and the sealing member 30 is made of epoxy resin. In this case, at least the adhesion surface 29a of the individual adhesion member 29 is made of any one of a metal, a glass epoxy plate, a paper epoxy substrate, a paper phenol substrate, and an epoxy resin plate material. For example, when the individual adhesion member 29 is formed of a glass epoxy plate, the adhesion strength between the adhesion member 29 and the sealing member 30 is 6.5 MPa. This adhesion strength is better than the adhesion strength (5 MPa) between the frame portion 21 (polyphenylene sulfide resin) and the sealing member 30 (epoxy resin). These adhesion members 29 are provided in the upper inner surface 27a1 of the frame portion 21 (the outer peripheral wall 21c) in the vicinity of the wires 26. Therefore, peeling of the sealing member 30 in the vicinity of the wires 26 is reduced in the unit storage portions 27 of the case 20 (the frame portion 21). Furthermore, when peeling of sealing member 30 is reduced, occurrence of cracking of sealing member 30 is reduced, and thus occurrence of breakage of the wires 26 is also reduced. As a result, deterioration in the reliability of the semiconductor device 1 is also suppressed.

Conventionally, in order to prevent the sealing member 30 from peeling off from the frame portion 21, the inner surface of the frame portion 21 is roughened or subjected to surface modification by ultraviolet (UV) irradiation or the like. However, such processing on the frame portion 21 is complicated and increases the number of manufacturing steps. On the other hand, in the case of the semiconductor device 1, prevention of the peeling of the sealing member 30 is achieved only by embedding the adhesion members 29 in the frame portion 21. That is, it is possible to prevent the peeling of the sealing member 30 while suppressing an increase in manufacturing cost.

In addition, due to the difference in linear expansion coefficient between the frame portion 21 (polyphenylene sulfide resin) and the sealing member 30 (epoxy resin), peeling of the sealing member 30 is likely to occur in the upper portion of the frame portion 21 (in the +Z direction). Therefore, it is desirable that the adhesion members 29 be embedded in the upper inner surface 27a1 of the frame portion 21 (the outer peripheral wall 21c) so as to cover the upper portion of the upper inner surface 27a1 in the vicinity of the wires 26.

Adhesion members 29 may also be provided in the inner surface 27a3 of the frame portion 21 (the outer peripheral wall 21a) in which the wires 26 are not provided and in which the first connection terminals 22a, 22b, and 22c and the second connection terminals 23a, 23b, and 23c, which h are less likely to break, are provided. Accordingly, peeling of the sealing member 30 in the unit storage portions 27 of the case 20 (the frame portion 21) is reduced.

Herein, the adhesion members 29 are embedded in the outer peripheral walls 21a and 21c of the frame portion 21, but may also be embedded in (the inner surfaces of) the outer peripheral walls 21b and 21d of the frame portion 21. As a result, peeling of the sealing member 30 from the frame portion 21 is further prevented.

### Second Embodiment

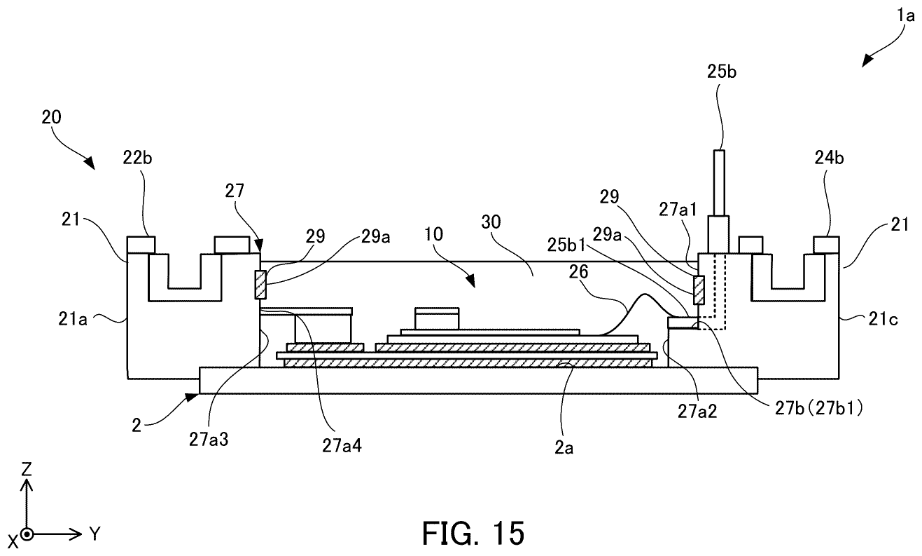

In a semiconductor device according to a second embodiment, adhesion members 29 equivalent to those according to the first embodiment protrude from an upper inner surface 27a1 and an inner surface 27a3 toward unit storage portions 27. This case will be described with reference to FIG. 15. FIG. 15 is a cross-sectional view of the semiconductor device according to the second embodiment. FIG. 15 corresponds to the cross-sectional view in FIG. 6 according to the first embodiment.

This semiconductor device 1a according to the second embodiment differs from the semiconductor device 1 according to the first embodiment in that adhesion surfaces 29a of the adhesion members 29 protrude toward the unit storage portions 27 beyond the upper inner surface 27a1 and the inner surface 27a3. That is, the adhesion members 29 form a step with respect to the upper inner surface 27a1 and the inner surface 27a3. Other configurations of the semiconductor device 1a may be the same as those of the semiconductor device 1.

As described above, due to the difference in linear expansion coefficient between the frame portion 21 (polyphenylene sulfide resin) and the sealing member 30 (epoxy resin), peeling of the sealing member 30 is likely to occur in the upper portions (+Z direction) of the upper inner surface 27a1 and the inner surface 27a3 of the frame portion 21. In the upper portion of the frame portion 21, the peeling of the sealing member 30 is likely to progress downward (in the −Z direction) along the upper inner surface 27a1 and the inner surface 27a3 of the frame portion 21.

Therefore, in the case of the semiconductor device 1a according to the second embodiment, by allowing the adhesion surfaces 29a of the adhesion members 29 to protrude toward the unit storage portions 27 from the upper inner surface 27a1 and the inner surface 27a3, the progress of the peeling of the sealing member 30 that has occurred in the upper portion of any one of the upper inner surface 27a1 and the inner surface 27a3 is prevented by the corresponding protruding adhesion member 29. Accordingly, in the semiconductor device 1a, peeling of the sealing member 30 in the unit storage portions 27 of the case 20 (the frame portion 21) is reduced as compared with the first embodiment.

The semiconductor device 1a is also manufactured in the same manner as in the first embodiment. However, the side surfaces of the recesses 3a2 and 3a3 of the fixed mold 3a in which the adhesion members 29 are provided are recessed further toward the inside of the fixed mold 3a as compared with the case according to the first embodiment so that the adhesion surfaces 29a of the adhesion members 29 protrude toward the unit storage portions 27 from the upper inner surface 27a1 and the inner surface 27a3. In the component setting step of step P11 of the manufacturing process of the case 20 illustrated in FIG. 10, the adhesion members 29 are provided in the recesses of the fixed mold 3a, and are set in the recesses 3a2 and 3a3 so as to protrude toward the inside with respect to the recesses 3a2 and 3a3. For example, the adhesion members 29 each are provided further inside than the adhesion members 29 in FIG. 12. In this state, the molding step of step P13 (FIG. 10) of the case 20 illustrated in FIG. 14 is performed, and step P14 is performed in the same way as that according to the first embodiment. In this way, the case 20 according to the semiconductor device 1a illustrated in FIG. 15 is obtained.

The technique disclosed herein prevents peeling of a sealing member.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a heat dissipation base having a top surface;
a case, including:
an outer peripheral wall, which is disposed on the top surface of the heat dissipation base, and has an inner surface facing an inside of the case, and
a wiring terminal provided integrally with the outer peripheral wall, the wiring terminal having an inner end portion, which is on one end of the wiring terminal and is exposed to the inside of the case from the inner surface of the outer peripheral wall;
a sealing member sealing the inside of the case; and
an adhesion member, which is embedded in the inner surface of the case and has an adhesion surface exposed from the inner surface, the adhesion member and the heat dissipation base being on different sides of the inner end portion of the wiring terminal,
wherein the adhesion surface has higher adhesion to the sealing member than the outer peripheral wall.

2. The semiconductor device according to claim 1, wherein the outer peripheral wall is made of polyphenylene sulfide resin.

3. The semiconductor device according to claim 1, wherein the sealing member is made of epoxy resin.

4. The semiconductor device according to claim 1, wherein the adhesion member is made of any one of a metal, a glass epoxy plate, a paper epoxy substrate, a paper phenol substrate, and an epoxy resin plate material.

5. The semiconductor device according to claim 1, wherein the adhesion member is made of a same material as a main material of the sealing member.

6. The semiconductor device according to claim 1, wherein the adhesion member is embedded in the inner surface, and the adhesion surface protrudes toward the inside from the inner surface.

7. The semiconductor device according to claim 1,
wherein the inner surface of the outer peripheral wall of the case has a step which protrudes toward the inside of the case, and
wherein the inner end portion of the wiring terminal is provided on the step.

8. The semiconductor device according to claim 7, further comprising a wire connected to the inner end portion of the wiring terminal on the step.

9. A semiconductor device manufacturing method, comprising:
preparing a wiring terminal including an inner end portion on one end thereof, an adhesion member including an adhesion surface, a heat dissipation base, and a sealing member;
forming a case having an outer peripheral wall, the outer peripheral wall having a bottom surface and an inner surface that faces an inside of the case, the wiring terminal and the adhesion member being integrally molded with the outer peripheral wall, with the inner end portion and the adhesion surface exposed to the inside of the case from the inner surface, the adhesion surface and the bottom surface being on two different sides of the inner end portion;
disposing the bottom surface of the outer peripheral wall on a top surface of the heat dissipation base; and
sealing the inside of the case on the top surface of the heat dissipation base with the sealing member.
